(19) United States
(12) Patent Application Publication
(10) Pub. No.: US 2009/0081810 A1
(43) Pub. Date: Mar. 26, 2009

(54) SUBSTRATE PROCESSING APPARATUS AND SUBSTRATE PROCESSING METHOD

(75) Inventors: Satomi Hamada, Tokyo (JP); Michihisa Kono, Tokyo (JP)

Correspondence Address: WENDEROTH, LIND & PONACK, L.L.P., 2033 K STREET N. W., SUITE 800, WASHINGTON, DC, 20006-1021, US

(73) Assignee: EBARA CORPORATION, Tokyo (JP)

(21) Appl. No.: 11/664,684

(22) PCT Filed: Sep. 22, 2005
(86) PCT No.: PCT/JP2005/017474

§ 371 Date: Aug. 21, 2008

(30) Foreign Application Priority Data
Oct. 6, 2004 (JP) 2004-293774
Nov. 19, 2004 (JP) 2004-336404

(51) Int. Cl. H01L 21/66; C23F 1/00

(52) U.S. Cl. 438/5; 156/345.15; 257/E21.521

(57) ABSTRACT

A substrate processing apparatus has a fluid supply means 20 for supplying fluid to a substrate W and a fluid collection means 21 for collecting the fluid in the vicinity of the substrate W, the fluid supply means 20 having a fluid spurt section 20a, the fluid collection means 21 having a fluid suction section 21a opening in the vicinity of the fluid spurt section 20a. Since the fluid collection means 21 suctions and collects the fluid floating around the substrate W as a result of the liquid having been supplied from the fluid spurt section 20a to the substrate W, it is possible to prevent the substrate W from being contaminated after the substrate W being processed with the fluid supplied from the fluid supply means 20.

### TECHNICAL FIELD

This invention relates to a substrate processing apparatus and a substrate processing method for processing a substrate by supplying fluid such as substrate processing liquid and/or gas to a substrate such as a semiconductor wafer and the like. This invention also relates to a substrate processing apparatus and a substrate processing method for processing a substrate such as a semiconductor wafer and the like, and more particularly relates to a substrate processing apparatus and a substrate processing method that make it possible to remove and collect liquid on the substrate while suppressing generation of watermarks in wet process.

### BACKGROUND ART

A substrate processing apparatus is conventionally known that processes a substrate such as a semiconductor wafer and the like by supplying chemical liquid such as etching liquid and substrate cleaning liquid (hereinafter collectively called “substrate processing liquid”) to top, back, and end faces of the substrate, or that dries the substrates by supplying gaseous substance such as gas containing components effective for the substrate processing. With this substrate processing apparatus, gaseous substance containing minute liquid particles generated from the substrate processing liquid when the fluid is supplied to the substrate and excessively supplied gas and the like float in the vicinity of the substrate. Such gaseous substance containing minute liquid particles of several micrometers or smaller in size and such gas are likely to remain in the atmosphere around the substrate as they are less likely to be affected with gravitational forces and easy to diffuse. However, when such gas and gaseous substance containing minute liquid particles stagnate around the substrate until the substrate processing step is over, the substrate finished with cleaning and drying steps is undesirably contaminated, which causes deterioration such as oxidation and corrosion of the substrate and generation of watermarks.

On one hand, when the substrates is cleaned with ultrasonic jet of pure water or the like, two-fluid jet, or water jet and the like, the greater speed of the jet, the higher removal ability of the substrate contamination. On the other hand, the greater speed of the jet, the higher supply rate of the minute liquid particles floating around the substrates, which becomes the cause of watermarks. In addition, when the substrates is cleaned with dry ice jet, pure water ice jet or the like for ejecting minute solid particles, the minute solid particles fly, which becomes the cause of watermarks. Also when a wide-width gas blow such as knife-edge is used to dry a substrate by blowing off liquid adhering to the substrates, it makes minute liquid particles fly and float, which causes watermarks. Moreover, when not only liquid particles but also evaporated chemical liquid (fluoric acid and the like) and gases (such as O₃ gas) generated from a gas solution water stagnate around the substrates, water marks may appear.

A conventional method for coping with the above problem has been, for example, to provide a discharge port at the side or bottom of the apparatus to force outside minute liquid particles, evaporated chemical liquid, and gasses flying and floating in the entire interior space of the apparatus. With this method, liquid particles and gasses present in the atmosphere in the interior space of the substrate processing apparatus are discharged.

On the other hand, there have also been a number of conventional methods of removing liquid adhering to the substrate surfaces, using centrifugal forces and shearing forces, such as spin drive method, gas blow method, etc. While these methods are effective for removing almost all the liquid on the substrate surfaces, it is difficult to remove thin layer of liquid adhering tightly to the substrate surfaces. Further, as liquid moves over the substrate surface during the process, the liquid is likely to remain at part of the substrate of a shape or material that is easy for such liquid to adhere to. For example, the liquid is hard to be discharged out of and likely to remain in recessed parts such as trenches and holes.

Even if liquid is once discharged out of recessed parts, there still remains the possibility that the liquid falls again in the recessed parts before reaching the substrate edge. Furthermore, a porous Low-k matelial (low-dielectric constant matelial) is likely infiltrated with liquid, and it is more difficult to remove liquid. For removing liquid from within the porous material, a method is proposed and practiced using boiling phenomenon caused by reducing pressure and/or heating. Such a method, however, not only necessitates air-tightness and large size of the apparatus, but also run the risk of film deterioration due to reducing pressure and/or heating.

The IPA (isopropyl alcohol) replacement method runs the risk of residual organic substance. As replacement speed and moving speed of the liquid are determined with the material properties of IPA, the lowest limit of the process cycle time is automatically determined, and so a high speed processing is difficult. As semiconductor devices become more highly integrated and wiring becomes more minute, now the lowest size of the watermark, problematic in device manufacture, has become more minute, and very little residue of liquid cannot be allowed. So a liquid removal method is desired that replaces conventional drying methods and that can be applied to wider range of applications with high performance.

### DISCLOSURE OF INVENTION

### Problems to be Solved by the Invention

However, the method of exhausting from the entire interior of the apparatus has a problem of very large flow rate of exhaust gas. In particular at the time of drying the substrate, the more the rotating speed of the substrate increase, the greater flow rate and pressure of exhaust gas are required, resulting in very great loads on various parts of the substrate processing apparatus. Further, for sufficient exhaust, a separate exhaust device is required, which becomes one of the causes of increase in the apparatus size. On the other hand, avoiding the influence of the atmosphere in the interior space of the apparatus on the substrate even without carrying out sufficient exhaust invites a problem of strict restriction required to be applied to substrate processing conditions such as substrate rotating speed and the supply rate of processing liquid. Further, while it is conceivable to cover the substrate surface with pure water until the atmosphere around the substrate restores the condition of the time before fluid such as substrate cleaning liquid and gas and the like are supplied, there is a problem of running the risk of increased amount of pure water to be used and time taken to process the substrate, and change of substrate film conditions.

This invention has been made in view of the above points, with an object of providing an apparatus and a method of processing a substrate that make it possible to increase the degree of cleanliness by efficiently removing gas and gaseous substance containing minute liquid particles stagnating around the substrates, thereby preventing post-process contamination of the substrates.

It is another object of this invention to provide an apparatus and a method of processing a substrate that make it possible to obtain dried substrate surfaces of high degree of cleanliness by applying a liquid removal method producing less liquid splash mist after wet type of processing.

### Means for Solving the Problems

(1) To achieve the above object, a substrate processing apparatus according to the present invention comprises, as shown in FIG. 1, for example, a fluid supply means 20 for supplying fluid to a substrate W; and a fluid collection means 21 for collecting the fluid in a vicinity of the substrate W, the fluid collection means 21 having a fluid suction section 21a, the fluid suction section 21a having an opening in a vicinity of a fluid spurt section 20a of the fluid supply means 20.

With the above constitution, as fluid is spurted from the fluid spurt section to the substrate, the fluid collection means suctions to collect the fluid floating in the vicinity of the substrate, so that the substrate after being processed with the fluid supplied from the fluid supply means is prevented from being contaminated.

(2) In the substrate processing apparatus as above (1) according to the present invention, the fluid collection means may be constituted to suction and collect the fluid floating in the vicinity of the substrate and minute particles contained in the fluid as a result of the fluid having been spurted from the fluid support section to the substrate.

In addition, the present invention relates to a substrate processing apparatus having fluid supply means for supplying fluid for processing a substrate by supplying fluid from the fluid supply means to the substrate, may further comprise a fluid collection means provided with a fluid suction section having an opening in the vicinity of the fluid spurt section of the fluid supply means for collecting fluid in the vicinity of the substrate, in which the fluid collection means suctions and collects the fluid floating in the vicinity of the substrate and minute particles contained in the fluid as the fluid is spurted from the fluid spurt section to the substrate.

With the above constitution, the fluid collection means suctions and collects the fluid floating in the vicinity of the substrate and minute particles contained in the fluid as the fluid is spurted from the fluid spurt section to the substrate. That is, the fluid supplied from the fluid supply means and minute particles produced by the supply of the fluid are collected efficiently by suctioning at a small suctioning rate before they are dispersed to a wide range, eliminating the possibility of the substrate being contaminated after the process.

(3) The substrate processing apparatus as above (1) or (2) according to the present invention may comprise, as shown in FIG. 1, for example, a control means 33 for controlling the fluid supply means 20 and the fluid collection means 21; and a measuring means 30 for measuring at least one of conditions of atmosphere around the substrate W, consisting of humidity, gas component, gas concentration, number of particles, and particle component; wherein measurement results with the measuring means 30 are fed back to the control means 33 to control supply of the fluid from the fluid supply means 20 and collection of the fluid to the collection means 21, so that the atmosphere is kept to predetermined conditions according to the measurement results of the atmosphere around the substrate W.

The above constitution makes it possible to feed back measurement results by the measuring means to the control means to control supply and collection of the fluid, to bring the atmosphere to a predetermined condition according to the measurement results of the condition of the atmosphere around the substrate, and to supply and collect the fluid at appropriate flow rate and timing according to the condition of the atmosphere around the substrate. This makes it possible to efficiently collect the minute particles and gas floating around the substrate before they are dispersed in a wide range as the fluid is supplied from the fluid supply means to the substrate.

(4) In the substrate processing apparatus as above in any one of (1) to (3) according to the present invention, the fluid supplied from the fluid supply means to the substrate may be at least one fluid selected from a group consisting of: pure water; gas solution water containing any of ozone, hydrogen, oxygen, nitrogen, argon, and carbon dioxide; chemical liquid containing any of isopropyl alcohol, fluoric acid, and sulfuric acid; and gas containing any of ozone, hydrogen, oxygen, nitrogen, argon, carbon dioxide, water vapor, IPA vapor, and air.

With the above constitution, the fluid supplied from the fluid supply means to the substrate is pure water, or gas solution water containing any of ozone, hydrogen, oxygen, nitrogen, argon, and carbon dioxide, chemical liquid containing any of isopropyl alcohol, fluoric acid, and sulfuric acid, or gas containing any of ozone, hydrogen, oxygen, nitrogen, argon, carbon dioxide, water vapor, IPA vapor, and air. Therefore, it is possible to prevent the processed substrate from being contaminated, as the fluid and minute particles, present as a result of supplying the fluid to the substrate, are suctioned to be collected.

(5) In the substrate processing apparatus (4) according to the present invention, the fluid supply means may have a supply mechanism for supplying to the substrate plural kinds of the pure water, gas solution water, chemical liquid, and gas; and the fluid collection means may have a collection mechanism for simultaneously suctioning and collecting gaseous substance and minute particles floating in the vicinity of the substrate as a result of plural kinds of the pure water, gas solution water, chemical liquid, and gas being supplied from the supply mechanism to the substrate.

With the above constitution, the fluid supply means has the mechanism for supplying plural kinds of pure water, gas solution water, chemical liquid, and gas. The fluid collection means has the mechanism for simultaneously suctioning and collecting gaseous substance and minute particles floating in the vicinity of the substrate as fluid is supplied from the fluid supply means. Therefore, the minute particles and gaseous substance are efficiently collected within a short period of time before they are dispersed in a wide range, so that the processed substrate is prevented from being contaminated.

(6) In the substrate processing apparatus as above in any one of (1) to (5) according to the present invention, the fluid supply means may be one of an ultrasonic jet, two-fluid jet, mist jet, and liquid jet for spurting minute liquid particles to the substrate, and a dry ice jet, ice jet, and microcapsule jet for spurting minute solid particles to the substrate.

With the above constitution, the fluid supply means is ultrasonic jet, two-fluid jet, mist jet, or liquid jet for spurting minute liquid particles to the substrate; or dry ice jet, ice jet, or microcapsule jet for spurting minute solid particles to the substrate. Therefore, there is no possibility of the processed substrate being contaminated as minute liquid particles and minute solid particles contained in the fluid spurted from the fluid supply means are suctioned to be collected efficiently before they are dispersed in a wide range.

(7) In the substrate processing apparatus (1) according to the present invention, the fluid suction section may be a liquid suction mechanism for suctioning liquid adhering to a surface of the substrate.

The above constitution, having the liquid suction mechanism for suctioning the liquid adhering to the substrate surface, makes it possible to remove liquid gently from the substrate without producing liquid scatter and mist. Further, in case the liquid is moved nearly vertically to the substrate and collected, liquid particles that have rolled do not adhere again to the substrate. Liquid present in recessed parts such as trenches and holes receives vertical forces under negative pressure by suction, and is easily removed.

(8) The substrate processing apparatus (7) according to the present invention may comprise, an evaporation acceleration mechanism for accelerating evaporation of the liquid after suctioning the liquid with the fluid suctioning mechanism by applying to the substrate surface at least one selected from a group consisting of: lamp exposure, gas supply, sound wave exposure, alcohol liquid supply, and alcohol vapor supply. Here, the alcohol may be any of methanol, ethanol, isopropyl alcohol, tri-fluoro-isopropyl alcohol, penta-fluoro-isopropyl alcohol, and hexa-fluoro-isopropyl alcohol; or a mixture thereof.

With the above constitution, having the evaporation acceleration mechanism, evaporation of liquid after the liquid being suctioned with the liquid suction mechanism is accelerated by applying to the substrate surface at least one of the following: lamp exposure, gas supply, sound wave exposure, supply of liquid such as alcohol or vapor. Therefore, it is possible to dry the substrate rapidly.

(9) The substrate processing apparatus (7) or (8) according to the present invention may comprise, a liquid supply mechanism for keeping supplying the liquid to the substrate surface until immediately before the liquid is suctioned with the liquid suctioning mechanism.

The above constitution, having the liquid supply mechanism to keep supplying liquid to the substrate surface until immediately before the start of suction, makes it possible to keep the substrate in the state of being covered with a liquid film until immediately before the start of suction and suppress generation of watermarks.

(10) A substrate processing apparatus according to the present invention may comprise a liquid supply mechanism for supplying liquid to a substrate surface; a liquid suction mechanism for suctioning the liquid adhering to the substrate surface; an evaporation accelerating mechanism for accelerating evaporation of the liquid by applying to the substrate at least one of lamp exposure and gas supply; a liquid film and liquid particle detection sensor for detecting residual liquid particles and a presence of liquid films on the substrate surface; and a control means for performing, according to a state of the residual liquid particles and the presence of liquid films on the substrate surface detected with the liquid film and liquid particle detection sensor, at least one control selected from a group consisting of: control of at least one of liquid supply rate and liquid supply time with the liquid supply mechanism, control of at least one of suction time and suction speed with the liquid suction mechanism, control of at least one of lamp exposure time and light intensity with the evaporation accelerating mechanism, and control of at least one of gas spurt time and gas temperature with the evaporation accelerating mechanism.

The above constitution has all or at least one chosen from: control means for controlling liquid supply rate and/or liquid supply time of the liquid supply mechanism; control means for controlling suction time and/or suction speed of the liquid suction mechanism; control means for controlling lamp exposure time and/or light intensity of the evaporation acceleration mechanism; and control means for controlling gas spurt time and/or gas temperature, according to the state of the residual liquid particles and the presence of liquid films on the substrate detected with the liquid film and liquid particle detection sensor. Therefore, it is possible to remove a liquid film and liquid particles completely and to prevent generation of watermarks.

Typically, controlling the suction time and/or suction speed makes it possible to suction liquid without interruption of a liquid film on the substrate. Further, controlling the liquid supply rate and/or liquid supply time makes it possible to keep covering the substrate with liquid until immediately before the start of suction and prevent watermarks from being generated due to immature drying of the substrate. In case supply start and stop time points are controlled, it is possible to carry out suction with less liquid splash. These operations serve as auxiliary conditions for carrying out suction that is neither too much nor too less. Controlling the lamp exposure time makes it possible to completely evaporate residual liquid on the substrate, and prevent excessive lamp exposure time, thereby reducing process time, amount of electricity consumption, and extending service life of the lamp. Controlling the light intensity of the lamp makes it possible to completely evaporate residual liquid on the substrate, reduce process time, and prevent corrosion due to intense light. Controlling the gas spurt time makes it possible to reduce process time and amount of gas used while completely evaporating residual liquid on the substrate. Controlling the gas temperature makes it possible to prevent the film from being denatured due to heat while completely evaporating residual liquid on the substrate.

(11) The substrate processing apparatus as above in any one of (7) to (10) according to the present invention may comprise a gaseous substance suction mechanism for suctioning atmosphere in a vicinity of the substrate surface.

The above constitution comprises the gaseous substance suction mechanism for suctioning atmosphere in a vicinity of the substrate surface. Therefore, splash and mist of liquid supplied with the liquid supply mechanism are suctioned effectively.

(12) The substrate processing apparatus as above in any one of (1) to (11) according to the present invention may comprise, as shown in FIG. 10, for example, a transfer section 55 for transferring the substrate; and a loading and unloading section 56 for transferring in and out the substrate.

The present invention may be characterized by having a wet process section for wet processing the substrate, a drying mechanism section for drying the substrate, a transfer section for transferring the substrate, and a loading and unloading section for transferring in and out the substrate, the drying mechanism section having a liquid suction mechanism for holding the substrate and suctioning liquid adhering to the substrate surface after the substrate being processed in the wet process section.

The above constitution makes it possible to realize a substrate processing apparatus having a plurality of substrate processing modules. In that case where the substrate processing device has a plurality of substrate processing modules, the number of substrate processed per unit time (throughput) increases.

(13) To achieve the above object, a substrate processing method according to the present invention comprises a fluid supply step of supplying fluid to a substrate; and a fluid collection step of collecting the fluid in a vicinity of the substrate in a vicinity of a supply point of the fluid supplied in the fluid supply step.

With the above constitution, fluid floating in the vicinity of the substrate is suctioned to be collected in the fluid collection process to prevent the substrate after being processed from being contaminated with fluid.

(14) In the substrate processing method as above (13) according to the present invention, the fluid may be spurted to the substrate in the fluid supply step, and the fluid and the minute particles contained in the fluid floating in the vicinity of the substrate as a result of the spurt may be suctioned to be collected in the fluid collection step.

With the above constitution, fluid floating in the vicinity of the substrate and minute particles contained in the fluid are suctioned to be collected. Therefore, it is possible to suction and collect fluid and minute particles produced by the supply of the fluid efficiently with a small suction rate before they are dispersed in a wide range so that contamination of the processed substrate is suppressed.

(15) The substrate processing method as above (13) or (14) according to the present invention may comprise a control step of controlling the fluid supply step and the fluid collection step; and a measuring step of measuring at least one atmospheric condition out of humidity, gas component, gas concentration, number of particles, and particle component, around the substrate; wherein measurement results by the measuring step are fed back to the control step to control supply of the fluid in the fluid supply step and collection of the fluid in the fluid collection step so that the atmosphere is kept to predetermined conditions according to the measurement results of the atmosphere around the substrate.

With the above constitution in which measurement results are fed back to the control process, fluid supply and fluid collection are controlled so that the condition of the atmosphere around the substrate is kept as specified according to the measurement results of the atmosphere. Therefore, it is possible to supply and collect fluid in appropriate rate and timing according to the condition of the atmosphere around the substrate. Thus, minute particles and gas floating around the substrate as the fluid is supplied are efficiently collected before they are dispersed in a wide range.

(16) In the substrate processing method as above in any one of (13) to (15) according to the present invention, the fluid supplied by the fluid supply step may be at least one fluid selected from a group consisting of: pure water; gas solution water containing any of ozone, hydrogen, oxygen, nitrogen, argon, and carbon dioxide; chemical liquid containing any of isopropyl alcohol, fluoric acid, and acid; and gas containing any of ozone, hydrogen, oxygen, nitrogen, argon, carbon dioxide, water vapor, IPA vapor, and air.

The above constitution makes it possible to prevent the processed substrate from being contaminated as the fluid and minute particles produced when the fluid is supplied are suctioned to be collected.

(17) In the substrate processing method as above (16) according to the present invention, the fluid supply step may include a supply step of supplying to the substrate plural kinds of the pure water, gas solution water, chemical liquid, and gas; and the fluid collection step may include a collection step of suctioning and collecting simultaneously gaseous substance and minute particles floating in the vicinity of the substrate as a result of the plural kinds of the pure water, gas solution water, chemical liquid, and gas being supplied to the substrate in the supply step.

The above constitution makes it possible to prevent the processed substrate from being contaminated as the minute particles and gaseous substance are collected efficiently within a short period of time before they are dispersed in a wide range.

(18) In the substrate processing method as above in any one of (13) to (17) according to the present invention, the fluid supply step may supply the fluid by at least one jet selected from a group consisting of an ultrasonic jet, a two-fluid jet, a mist jet, and a liquid jet for spurting minute liquid particles to the substrate; and a dry ice jet, an ice jet, and a microcapsule jet for spurting minute solid particles to the substrate.

The above constitution makes it possible to prevent the processed substrate from being contaminated as the minute liquid particles and the minute solid particles contained in the spurted fluid are suctioned to be collected efficiently before they are dispersed in a wide range.

(19) In the substrate processing method as above (13) according to the present invention, the fluid suction step may be a liquid suction step of suctioning liquid adhering to the substrate surface.

The above constitution makes it possible to remove the liquid gently from the substrate without producing liquid splash and mist as the liquid adhering to the substrate is suctioned. Further, in case the liquid is moved nearly vertically to the substrate and collected, liquid particles that have rolled do not adhere again to the substrate. Liquid present in recessed parts such as trenches and holes receives vertical forces under negative pressure by suction, and is easily removed.

(20) In a substrate processing method according to the present invention, gaseous substance around a position of a substrate toward which a fluid is supplied to the substrate and minute particles contained in the gaseous substance may be suctioned and collected simultaneously with supplying the fluid to the substrate.

With the above constitution of the substrate processing method of supplying the fluid to the substrate, as the gaseous substance around the position of a substrate toward which a fluid is supplied to the substrate and the minute particles contained in the gaseous substance are simultaneously suctioned and collected, the minute particles and gaseous substance floating in the vicinity of the substrate as the fluid is supplied to the substrate are suctioned to be collected efficiently within a short period of time before they are dispersed in a wide range and the processed substrate is prevented from being contaminated.

(21) A substrate processing method according to the present invention may comprise the steps of, processing a substrate by supplying liquid to a surface of the substrate; and suctioning the liquid adhering to the substrate surface.

The invention may also be characterized by suctioning liquid adhering to the substrate surface after processing the substrate with the supply of the fluid to the substrate.

With the above constitution, as the liquid adhering to the substrate surface is suctioned after processing the substrate with the supply of the fluid to the substrate, it is possible to remove the liquid gently from the substrate without producing liquid splash and mist. Further, in case the liquid is moved nearly vertically to the substrate and collected, liquid particles that have rolled do not adhere again to the substrate. Liquid present in recessed parts such as trenches and holes receives vertical forces under negative pressure by suction, and is easily removed.

(22) The substrate processing method as above (21) according to the present invention may comprise the step of, accelerating evaporation of the liquid after suctioning to remove the liquid adhering to the substrate surface by applying to the substrate surface at least one selected from a group consisting of: lamp exposure, gas supply, sound wave exposure, alcohol liquid supply, and alcohol vapor supply. Here, the alcohol may be any of methanol, ethanol, isopropyl alcohol, tri-fluoro-isopropyl alcohol, penta-fluoro-isopropyl alcohol, and hexa-fluoro-isopropyl alcohol; or a mixture thereof.

The above constitution makes it possible to accelerate evaporation of the liquid to rapidly dry the substrate by the lamp exposure, supply of gas, sound exposure, or supply of liquid such as alcohol or vapor to the substrate surface after suctioning to remove the liquid adhering to the substrate surface.

(23) The substrate processing method as above (22) according to the present invention may comprise the step of changing, according to a state of residual liquid particles and the presence of liquid films on the substrate surface, at least one selected from a group consisting of: at least one of the liquid supply rate and liquid supply time; at least one of the liquid suction time and liquid suction speed; at least one of the lamp exposure time and light intensity of the lamp; at least one of the sound wave exposure time and sound wave intensity; and at least one of supply time and temperature of the alcohol liquid or alcohol vapor.

The above constitution makes it possible to completely remove the liquid film and suppress generation of watermarks by changing, according to the state of residual liquid particles and the presence of liquid films on the substrate, all or at least one of the items chosen from: liquid supply rate and/or liquid supply time; liquid suction time and/or liquid suction speed; lamp exposure time and/or light intensity; sound wave exposure time and/or sound wave intensity; and supply time and/or temperature of vapor or liquid such as alcohol.

(24) In the substrate processing method as above in any one of (21) to (23) according to the present invention, the liquid may be kept supplied to the substrate until immediately before the start of suction of the liquid.

With the above constitution, as the liquid is kept supplied to the substrate until immediately before the liquid is suctioned, it is possible to keep the substrate in the state of being covered with the liquid film until immediately before the suction so that watermarks are suppressed from being generated.

Further, the substrate processing apparatus as described in any one of (1) through (12) may be provided with an antistatic mechanism to prevent static-electrical charges on the substrate to prevent the substrate from being damaged with static-electrical charges.

This application is based on the Patent Applications No. 2004-293774 filed on Oct. 6, 2004 and 2004-336404 filed on Nov. 19, 2004 in Japan, the contents of which are hereby incorporated in its entirety by reference into the present application, as part thereof.

The present invention will become more fully understood from the detailed description given hereinbelow. However, the detailed description and the specific embodiment are illustrated of desired embodiments of the present invention and are described only for the purpose of explanation. Various changes and modifications will be apparent to those ordinary skilled in the art on the basis of the detailed description.

The applicant has no intention to give to public any disclosed embodiment. Among the disclosed changes and modifications, those which may not literally fall within the scope of the patent claims constitute, therefore, a part of the present invention in the sense of doctrine of equivalents.

The use of the terms “a” and “an” and “the” and similar referents in the context of describing the invention (especially in the context of the following claims) are to be construed to cover both the singular and the plural, unless otherwise indicated herein or clearly contradicted by context. The use of any and all examples, or exemplary language (e.g., “such as”) provided herein, is intended merely to better illuminate the invention and does not pose a limitation on the scope of the invention unless otherwise claimed.

### EFFECTS OF THE INVENTION

According to the present invention, the substrate after being processed is suppressed from being contaminated as the fluid collection means suctions to collect the fluid floating in the vicinity of the substrate.

Further according to the present invention, in case the fluid collection means suctions to collect the fluid floating in the vicinity of the substrate and minute particles contained in the fluid as the fluid is spurted from the fluid spurt section to the substrate, it is possible to efficiently suction to collect with a small suction rate the fluid supplied from the fluid supply means and minute particles produced by the supply of the fluid before they are dispersed in a wide range to eliminate the possibility of contamination of the substrate after it is processed.

Further according to the present invention, in case the fluid suction mechanism for suctioning the liquid adhering to the substrate is provided, it is possible to remove the liquid gently from the substrate without producing liquid splash and mist. Further, when the liquid is moved nearly vertically to the substrate and collected, liquid particles that have rolled do not adhere again to the substrate. Liquid present in recessed parts such as trenches and holes receives vertical forces under negative pressure by suction, and is easily removed.

Further according to the present invention, in case gaseous substance around the position of a substrate toward which the fluid is supplied to the substrate and minute particles contained in the gaseous substance are simultaneously suctioned and collected when fluid is supplied to the substrate, the minute particles and gaseous substance floating in the vicinity of the substrate as the fluid is supplied to the substrate are efficiently suctioned to be collected within a short period of time before they are dispersed in a wide range and the processed substrate is prevented from being contaminated.

Further according to the present invention, in case the fluid adhering to the substrate surface is suctioned, it is possible to gently remove the liquid from the substrate without producing liquid splash and mist. Further, in case the liquid is moved nearly vertically to the substrate and collected, liquid particles that have rolled do not adhere again to the substrate.

### BRIEF DESCRIPTION OF DRAWINGS

FIG. 1 shows the constitution of a substrate processing apparatus in an embodiment of the present invention.

FIG. 2 shows the constitution of a gas supply nozzle and a suction section provided in a substrate processing apparatus in another embodiment of the present invention.

FIG. 3 is a graph of relationship between spurting gas supply rate and number of minute liquid particles, with and without suction.

FIG. 4 is a bar chart of comparison of the number of minute liquid particles under different conditions of substrate processing.

FIG. 5 is a schematic view of an example constitution of a drying mechanism section of the substrate processing apparatus according to the present invention.

FIG. 6 is a schematic view of an example constitution of an essential part of a drying mechanism section of the substrate processing apparatus according to the present invention.

FIG. 7 is a schematic view of an example constitution of an essential part of the drying mechanism section of the substrate processing apparatus according to the present invention.

FIG. 8 is a schematic view of an example constitution of an essential part of the drying mechanism section of the substrate processing apparatus according to the present invention.

FIG. 9A is a schematic view of an example constitution of an essential part of the drying mechanism section of the substrate processing apparatus according to the present invention.

FIG. 9B is a schematic view of an example constitution of an essential part of the drying mechanism section of the substrate processing apparatus according to the present invention.

FIG. 10 is an overall schematic plan view of constitution of the substrate processing apparatus according to the present invention.

FIG. 11A is a schematic view of a substrate rotating mechanism in the roll cleaning machine.

FIG. 11B is a schematic view of a substrate cleaning mechanism in the roll cleaning machine.

FIG. 12A is an overall schematic view of the pen cleaning machine.

FIG. 12B is a schematic view of an essential part of the pen cleaning machine.

### DESCRIPTION OF REFERENCE NUMERALS AND SYMBOLS

10: rotary table
11: main part
12: substrate holding chuck
13, 13A: rotary shaft
15: substrate holding mechanism
20: substrate processing liquid supply nozzle
20a: jet port
21: suction nozzle
21a: suction port
22: substrate processing liquid supply nozzle
22a: jet port
23: suction nozzle
23a: suction port
25: anti-splash cup
25A: liquid collection cover
26: drain pipe
26A: discharge port
27: casing
30: sensor
31: suction adjuster
31A: suction adjuster
32: substrate processing liquid supply adjuster
32A: supply rate adjuster
33: controller
33A: controller
35: liquid supply nozzle
35a: liquid jet port
36: suction nozzle
36a: suction port
37: liquid film and liquid particle detection sensor
40: gas supply nozzle
40a: supply port
41: suction section
41a: suction port
42: substrate processing liquid
43: gas
44: minute liquid particle
45: measuring point
46: liquid supply nozzle
47: suction nozzle
48: gas supply nozzle
50: substrate processing apparatus
51: wet process section
52: wet process section
53: wet process section
54: dry process section
55: transfer section
56: loading and unloading section
W: substrate

### BEST MODE FOR CARRYING OUT THE INVENTION

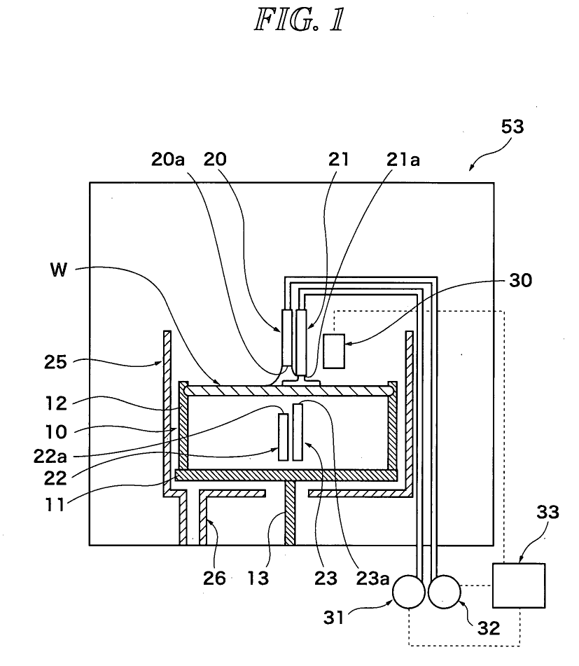

FIG. 1 shows an example constitution of the substrate processing apparatus 53 in an embodiment of the present invention. The substrate processing apparatus 53 is a cleaning machine as a module of the substrate processing apparatus in a broad sense constituted with a CMP, a scruber, a dryer, etc. This substrate processing apparatus 53 is constituted with a rotary table 10 made up of a main part 11 of a planar shape and a plurality of substrate holding chucks 12 erected on the periphery of the main part 11. The rotary table 10 is placed on a rotary shaft 13 rotated with a drive means (not shown) so as to rotate with a substrate W, such as a semiconductor wafer, held generally horizontal on the inner sides of the substrate holding chucks 12. On the other hand, a substrate processing liquid supply nozzle 20, as a fluid supply means, opening toward the top side of the wafer W held with the substrate holding chucks 12, is provided above the substrate W. The substrate processing liquid supply nozzle 20 is to supply chemical liquid such as etching liquid and various kinds of liquid such as cleaning liquid to the substrate W when the substrate W is processed. Here, the liquid supplied from the substrate processing liquid supply nozzle 20 is enumerated as: pure water, gas solution water containing any of ozone, hydrogen, oxygen, nitrogen, argon, and carbon dioxide, and chemical liquid (substrate processing liquid) containing any of isopropyl alcohol, fluoric acid, and sulfuric acid. In other words, the substrate processing liquid is a fluid that contains at least one of pure water, gas solution water, and chemical liquid. The gas solution water contains any of ozone, hydrogen, oxygen, nitrogen, argon, and carbon dioxide. The chemical liquid contains any of isopropyl alcohol, fluoric acid, and sulfuric acid.

A suction nozzle 21 as a fluid collection means is provided adjacent to the substrate processing liquid supply nozzle 20. The suction nozzle 21 is capable enough of suctioning simultaneously gaseous substance in the vicinity of the substrate W and minute particles contained in the gaseous substance. A suction port 21a of the suction nozzle 21 is placed in a position that is near the top side of the substrate W and in the vicinity of a jet port 20a of the substrate processing liquid supply nozzle 20. Incidentally, while the minute particle in this embodiment is meant to be of a size of about 0.1 to 10 micrometers, typically 0.1 to 5 micrometers, the size may be changed appropriately according to requirements of the substrate processing apparatus.

In case the substrate processing liquid is to be supplied also to the reverse side of the substrate W, as shown in FIG. 1, a substrate processing liquid supply nozzle 22 is also provided below the substrate W. The substrate processing liquid supply nozzle 22 is open toward the reverse side of the substrate W. A suction nozzle 23 is placed adjacent to the substrate processing liquid supply nozzle 22. The suction port 23a of the suction nozzle 23 is placed in a position that is in the vicinity of the reverse side of the substrate W and in the vicinity of the jet port 22a of the substrate processing liquid supply nozzle 22.

The substrate processing liquid supply nozzle 20 and the suction nozzle 21 in their installed positions are provided with a swing mechanism so that the jet port 20a and suction port 21a swing as a single set along the surface of the substrate W. Likewise, the substrate processing liquid supply nozzle 22 and the suction nozzle 23 in their installed positions are provided with a swing mechanism so that the jet port 22a and suction port 23a swing as a single set along the surface of the substrate W. That is to say, it is constituted that the jet port 20a and the suction port 21a swing from a position facing the center to a position facing the periphery of the surface of the substrate W, and that the jet port 22a and the suction port 23a swing from a position facing the center to a position facing the periphery of the reverse surface of the substrate W. Here, with respect to the travel direction of respective nozzles, the substrate processing liquid supply nozzles 20 and 22 are located before or after the suction nozzles 21 and 23.

While FIG. 1 shows a case in which the substrate processing liquid supply nozzles 20 and 22 are provided one for each on the top and reverse side of the substrate W, a plurality of substrate processing liquid supply nozzles may be provided so that a plural kinds of substrate processing liquid may be supplied such as gas solution water, chemical liquid, pure water, etc. It is also possible to change the positions of the nozzles, and position and angle of jet of substrate processing liquid as required. The substrate processing liquid supply nozzles 20 and 22 may use, in addition to the above, an ultrasonic jet of pure water or the like, two-fluid jet, a mist jet, or liquid jet for spurting minute liquid particles; or a dry ice jet, an ice jet, or a microcapsule jet, etcetera for spurting solid particles. Incidentally, the solid particle includes pure water, gas solution water, liquid agent, gas, etcetera in solidified form.

On the other hand, an anti-splash cup 25 is provided in a position surrounding the side of the rotary table 10 to prevent splash of substrate processing liquid supplied to the substrate W. The bottom of the anti-splash cup 25 is connected to a drain pipe 26 for collecting substrate processing liquid used for processing the substrate.

A sensor 30, as a measuring means, such as a particle counter for counting the number of particles in the gaseous substance and a gas concentration meter for measuring gas concentration, is disposed near the substrate W. The sensor 30 makes it possible to measure one or more of atmospheric conditions such as moisture, gas component, gas concentration, number of particles, and particle component around the substrate W. There are also provided a suction adjuster 31 for adjusting the suction rate and suction timing of the suction nozzle 21, and a substrate processing liquid supply adjuster 32 for adjusting the substrate processing liquid supply rate and supply timing of the substrate processing liquid supply nozzle 20. The suction adjuster 31 and the substrate processing liquid supply adjuster 32 are adapted to be controlled with a controller 33 that receives signals from the sensor 30. In other words, atmospheric conditions around the substrate W in the substrate processing device 53 are measured with the sensor 30. The measurement signals are sent from the sensor 30 to the controller 33. According to the measurement results, the controller 33 controls the suction adjuster 31 and the substrate processing liquid supply adjuster 32 to realize appropriate rates of supply and suction of the substrate processing liquid that reduce atmospheric contamination around the substrate W.

Sequential steps of processing the substrate with the substrate processing apparatus 53 are described. In the state of the substrate W held with the substrate holding chucks 12, the rotary table 10 is rotated. In this state, substrate processing liquid such as chemical liquid or cleaning liquid is supplied from the substrate processing liquid supply nozzle 20 to the substrate W to process the substrate W. Here, simultaneously with supplying substrate processing liquid from the substrate processing liquid supply nozzle 20, gaseous substance in the vicinity of the substrate W is suctioned with the suction nozzle 21 to collect the gaseous substance present in the vicinity of the substrate W together with minute particles contained in the gaseous substance. As a result, the gaseous substance containing minute liquid particles produced with the substrate processing liquid jetted out of the substrate processing liquid supply nozzle 20 is suctioned to be collected before it is dispersed in a wide range. In this way, it is possible to efficiently suction to collect within a short period of time the gaseous substance containing minute liquid particles flown from the supplied substrate processing liquid by suctioning with the suction nozzle 21 simultaneously with the supply of substrate processing liquid from the substrate processing liquid supply nozzle 20. Further, as the suction port 21a of the suction nozzle 21 is open in the vicinity of the jet port 20a of the substrate processing liquid supply nozzle 20, it is possible to efficiently suction to collect with a small suction rate the gaseous substance containing minute liquid particles. While the above description is on the case where chemical liquid and cleaning liquid are supplied from the substrate processing liquid supply nozzle 20, the process may be carried out by supplying substrate processing liquid such as chemical liquid and cleaning liquid not only from the substrate processing liquid supply nozzle 20 to the top side of the substrate W but also from the substrate processing liquid supply nozzle 22 to the reverse side of the substrate W. In that case, the gaseous substance in the vicinity of the reverse side of the substrate W is suctioned to be collected with the suction nozzle 23.

When the process is carried out by spurting substrate processing liquid, while rotating the substrate W, the spurting is made while swinging the substrate processing liquid supply nozzle 20 and the suction nozzle 21, so that the jet port 20a and the suction port 21a move from a position facing the center to a position facing the periphery of the substrate W surface. As a result, the substrate W is uniformly processed as the substrate processing liquid is spurted over the entire top surface of the substrate W. Here, as the jet port 20a and the suction port 21a move as a single set, it is possible to securely collect the gaseous substance containing the minute liquid particles flown with the supplied substrate processing liquid. The swing speed of the substrate processing liquid supply nozzle 20 and the suction nozzle 21 is made to decrease as they move from the center toward the periphery of the substrate W, and the supply rate of the substrate processing liquid and/or suction rate is made to increase as the nozzles move from the center toward the periphery of the substrate W. In this way, it is possible to process the entire substrate W all the more uniformly.

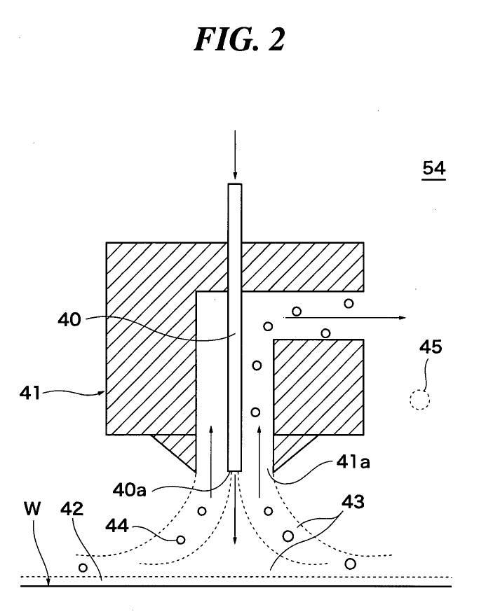

FIG. 2 shows an example constitution of a fluid supply means and a fluid collecting means provided in a substrate processing apparatus 54 in another embodiment of the present invention. The substrate processing apparatus 54 is a drying mechanism section as a single module of the substrate processing apparatus in a broad sense. Incidentally, parts in this embodiment other than those indicated in the drawing are the same as those of the substrate processing apparatus 53 shown in FIG. 1 and so their detailed explanations are omitted. This substrate processing apparatus 54 has a gas supply nozzle 40 and a suction section 41, constituting a single set. In other words, while the gas supply nozzle 40 as a gas supply means is disposed for supplying gas such as N₂ gas to the top surface of the substrate W, the suction section 41 as a fluid collecting means is placed outside of the gas supply nozzle 40 such that the suction port 41a is in a position to surround the supply port 40a of the gas supply nozzle 40. The supply port 40a of the gas supply nozzle 40 is disposed in a position and at an angle to make it possible to blow off with jet gas the substrate processing liquid 42 adhering to the substrate W surface. The gas supplied from the gas supply nozzle 40 to the substrate W may be, besides N₂ gas mentioned above, any gas that contains one of ozone, hydrogen, oxygen, argon, carbon dioxide, water vapor, isopropyl alcohol (IPA) vapor, and air.

This substrate processing apparatus 54 carries out a drying process of blowing off the substrate processing liquid 42 adhering to the substrate W by spurting-supplying gas 43 from the gas supply nozzle 40 to the substrate W. Here, while the gas 43 is supplied from the gas supply nozzle 40, the suction section 41 suctions to collect the gaseous substance in the vicinity of the substrate W. As a result, the gas 43 jetting out of the gas supply nozzle 40, bouncing back from the substrate W and spreading around, and the gaseous substance containing minute liquid particles 44 of the substrate processing liquid flying with the gas 43, are suctioned to be collected. In other words, the suction section 41 suctions to collect the gas 43 together with the minute liquid particles 44 present in the vicinity of the substrate W. In this way, it is possible to efficiently suction to collect with a small suction rate the supplied gas 43 and the gaseous substance containing minute liquid particles 44 before they are dispersed in a wide range by suctioning to collect them while the gas 43 is supplied from the gas supply nozzle 40. Further, as the suction port 41a of the suction section 41 is open in a position surrounding the supply port 40a of the gas supply nozzle 40, the supplied gas 43 and the flying minute liquid particles 44 are collected before they are dispersed in a wide range.

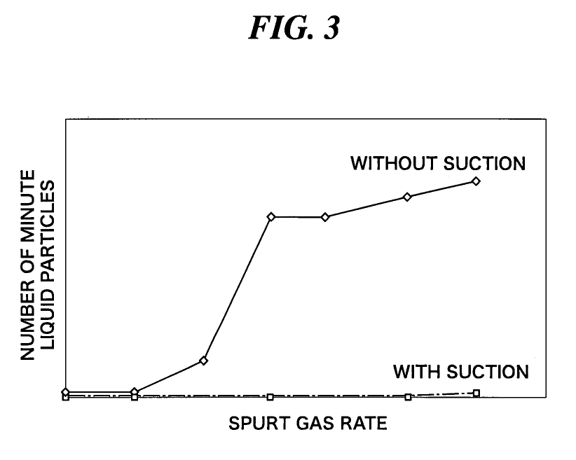

FIG. 3 is a graph of measurements of the number of minute liquid particles 44 in the gaseous substance at the measuring point 45 shown in FIG. 2 when the substrate W is processed with the substrate processing apparatus 54 equipped with the gas supply nozzle 40 and the suction section 41. In the graph, the solid curve represents the data without suctioning with the suction section 41, while the dashed-dotted curve represents the data with suctioning with the suction section 41. When the gas 43 is spurted to the surface of the substrate W which the substrate processing liquid 42 is adhering to, a large number of minute liquid particles 44 fly away. As seen from the figure, when the suction is not made, the number of minute liquid particles 44 flying around the substrate W increases with the increase in the supply rate of the gas 43 spurted from the gas supply nozzle 40. However, as shown in the same figure, when suction is made with the suction section 41, the number of minute liquid particles 44 at the measuring point 45 is held down to about 1/100 to 1/500 in comparison with the number without suction in spite of the increased supply rate of the gas 43 spurted from the gas supply nozzle 40.

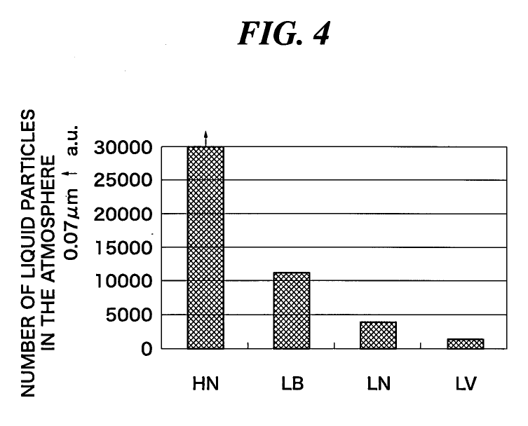

FIG. 4 is a bar chart of comparison of the number of minute liquid particles under four different conditions of substrate processing. Measurements of the number of minute liquid particles were taken at a position about 100 mm above an edge of the substrate W. In the graph, the symbol HN represents the number of minute liquid particles when the substrate is turned at a high speed of 2000 rpm, LB when the substrate is turned at a low speed of 100 rpm and gas is blown, LN when the substrate is simply turned at a low speed of 100 rpm, and LV when the substrate is turned at a low speed of 100 rpm and suction is made, respectively. At the high revolution (of an extent typically used for drying the substrate) indicated with HN, liquid film is broken at the substrate edge into a large number of liquid particles (the number of liquid particles exceeded measurement limit). In contrast, at the low revolution with gas blow indicated with LB, the number of liquid particles was half or less than half. At the low revolution (of an extent causing no drying) without gas blow indicated with LN, the number of liquid particles decreased further. At the low substrate revolution combined with suction as indicated with LV, in comparison to the case with gas blow, liquid splashes less and the liquid film reaching the substrate edge is thinner, so that the number of liquid particles produced decreases and so the number of liquid particles in the gas decreases. As is seen from the above graph, the conventional, generally practiced method of drying by rotating the substrate together with gas blow makes the liquid on the substrate break into minute particles when the liquid is removed, and minute liquid particles fly and disperse in the atmosphere. The method of removing liquid by suction produces less liquid splash and therefore reduces the cause of watermarks.

As described above, suctioning and collecting the gaseous substance in the vicinity of the substrate W through the suction section 41 at the time of cleaning and drying the substrate W makes it possible to prevent minute liquid particles of the substrate processing liquid and supplied gas from re-adhering to the substrate W and prevent watermarks from being produced. Further, as scattered minute liquid particles, gas of chemical liquid, and floating excessive gas are suctioned in the vicinity of the jet port 20a and the supply port 40a, they are collected efficiently before they are dispersed over the entire atmosphere in the substrate processing apparatus. Therefore it is possible to efficiently collect, with a small suction rate, contaminants in the atmosphere in the apparatus and prevent the substrate W and the apparatus from being contaminated. Further, as the minute liquid particles and gas are securely collected with a small suction rate, it is possible to downsize and simplify the substrate processing apparatus.

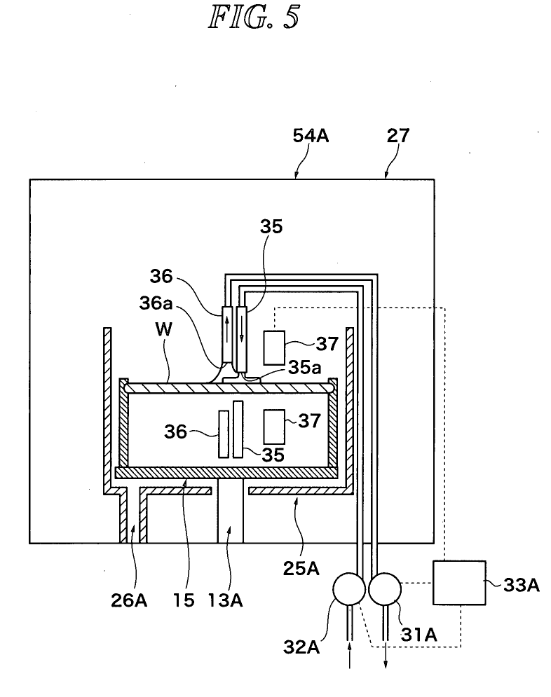

FIG. 5 is a schematic view of an example constitution of a drying mechanism section 54A. The drying mechanism section 54A has a casing 27 and a substrate holding mechanism 15 for holding the substrate W and rotating about a rotary shaft 13A in the casing 27. The substrate holding mechanism 15 is surrounded with a liquid collection cover 25A having a drain hole 26A for draining collected liquid. A liquid supply nozzle 35 supplies liquid onto the top surface of the substrate W. A suction nozzle 36 suctions liquid from the top surface of the substrate W. The liquid supply nozzle 35 and the suction nozzle 36 are disposed with their liquid jet port 35a and liquid suction port 36a close to each other.

A liquid film and liquid particle detection sensor 37 is to detect the presence of liquid film and residual liquid particles. A supply rate adjuster 32A is to adjust the supply rate and timing of supplying liquid from the nozzle 35. A suction adjuster 31A is to adjust suction rate and timing of suctioning liquid. Detection output of the liquid film and liquid particle detection sensor 37 is inputted to a controller 33A. The controller 33A controls the supply rate adjuster 32A according to the detection output of the liquid film and liquid particle detection sensor 37 for the presence of liquid film and residual liquid particles to adjust the liquid supply rate supplied from the liquid supply nozzle 35, and also controls the suction adjuster 31A to adjust the suction force of the suction nozzle 36.

In the drying mechanism section 54A of the above constitution, the substrate W held with the substrate holding mechanism 15 is rotated and cleaned by supplying liquid (such as cleaning liquid) from the liquid supply nozzle 35. Immediately after the cleaning step, drying step is carried out, in which the suction nozzle 36 is moved from the center of the substrate W toward the periphery, while the suction nozzle 36 suctions liquid adhering to the surface of the substrate W. This makes it possible to keep the substrate W in the state of being covered with liquid film until immediately before the liquid is suctioned, and to prevent watermarks from being produced. Further, the liquid film and liquid particle detection sensor 37 detects presence of liquid film and residual liquid particles on the surface of the substrate W, and according to the detection, supply rate and time of supplying liquid from the liquid supply nozzle 35, and suction force and suction time of the suction nozzle 36 are adjusted. Therefore, it is possible to further suppress generation of watermarks. Incidentally, the drying process may be made at a higher rotation speed of the substrate W than in the cleaning process to accelerate drying.

While the above example is provided in which liquid (for example cleaning liquid) is supplied from the liquid supply nozzle 35 to the top surface of the substrate W and the liquid adhering to the top surface is suctioned with the suction nozzle 36, the invention is not limited to the above. As shown in the figure, the liquid supply nozzle 35 and the suction nozzle 36 may be disposed also under the substrate W so as to face the reverse surface of the substrate W so that liquid may be supplied from the liquid supply nozzle 35 to the reverse surface of the substrate W and then residual liquid may be suctioned with the suction nozzle 36. In this case, the liquid film and liquid particle detection sensor 37 may be provided also under the substrate W to make it possible to detect presence of the liquid film and residual liquid particles on the reverse surface of the substrate W. Further, although not shown in the figure, it may be possible to dispose a liquid supply nozzle for supplying liquid to the periphery of the substrate W and a suction nozzle for suctioning residual liquid around the periphery of the substrate W to supply liquid and suction residual liquid.

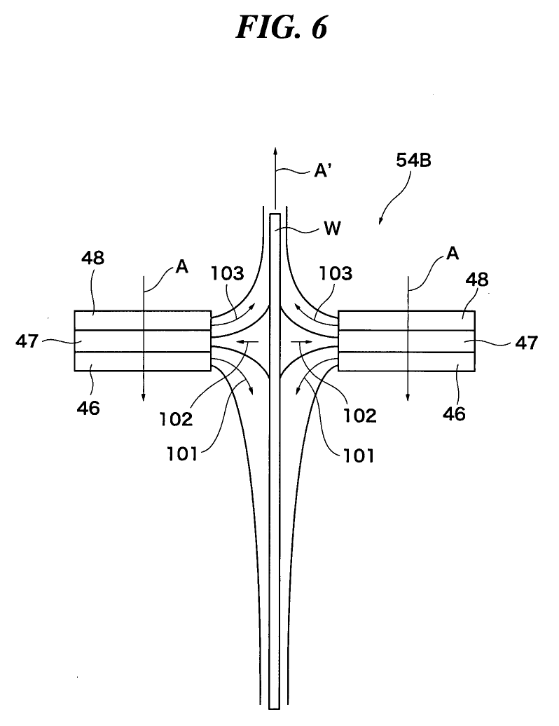

FIG. 6 is a schematic view of general constitution of essential part of the drying mechanism section in another embodiment. In the drawing, the upward direction on the drawing surface corresponds actual, vertical upward direction. The substrate W is disposed so that its processed surfaces face to horizontal direction. As shown in the drawing, this drying mechanism section 54B has: liquid supply nozzles 46, suction nozzles 47, and gas supply nozzles 48, one each on both sides of the substrate W, with one nozzle placed over another. A reciprocation mechanism (not shown in the drawing) is provided to enable a reciprocal movement of the respective nozzles. The mechanism enables top to down motion, as shown with the arrow A, of the liquid supply nozzles 46, suction nozzles 47, and gas supply nozzles 48. Respective nozzles are disposed in a casing 27 (See FIG. 5). The liquid supply nozzles 46, suction nozzles 47, and gas supply nozzles 48 disposed in a row in the direction parallel to the substrate W and also at right angles to the arrow A direction to cover the diameter of the substrate W. It may alternatively be arranged that respective nozzles cover at least part of the substrate W and, while the substrate W is moved in the arrow A′ direction, move reciprocally in the direction parallel to the substrate W and also at right angles to the arrow A′ direction so as to cover the diameter of the substrate W. Constituting the drying mechanism section 54B as described above makes it possible to apply the drying process over the entire surface of the substrate W.

In the drying mechanism section of the above constitution, when liquid (for example cleaning liquid) 101 is supplied from the liquid supply nozzle 46 to both surfaces of the substrate W while the liquid supply nozzles 46, suction nozzles 47, and gas supply nozzles 48 are moved from up downward along the substrate W, the cleaning water 101 flows down covering the both surfaces of the substrate W by the gravitational force. Along with suctioning and removing with the suction nozzle 47 residual cleaning liquid 102 on the both surfaces of the substrate W, dry inert gas (such as N₂ gas) is supplied from the gas supply nozzle 48 to the both surfaces of the substrate W so as to remove by evaporation the slightly remaining residual liquid thereon.

Incidentally, while the example shown in FIG. 6 is assumed to dispose the processed surface of the substrate W in the horizontal direction and move the respective nozzles 46, 47, and 48 in the vertical direction, it may alternatively dispose the processed surface of the substrate W in the vertical direction and move the respective nozzles 46, 47, and 48 in the horizontal direction.

As described above, removal by the suction of the residual cleaning liquid 102 with the suction nozzle 47, followed by the supply of dry inert gas 103 from the gas supply nozzle 48 to remove by evaporation the slight residual cleaning liquid on the both surfaces of the substrate W, makes it possible to suppress generation of watermarks. Although not shown in the drawing, a liquid film and liquid particle detection sensor is provided to detect the presence of liquid film and residual liquid particles on the both surfaces of the substrate W to adjust the liquid supply rate supplied from the liquid supply nozzle 46, the suction force of the suction nozzle 47, and the supply rate of gas supplied from the gas supply nozzle 48 in accordance with the detection output of the liquid film and liquid particle detection sensor. Therefore, it is possible to further suppress watermarks from being produced. It may also be arranged to adjust the temperature of the inert gas supplied from the gas supply nozzle 48.

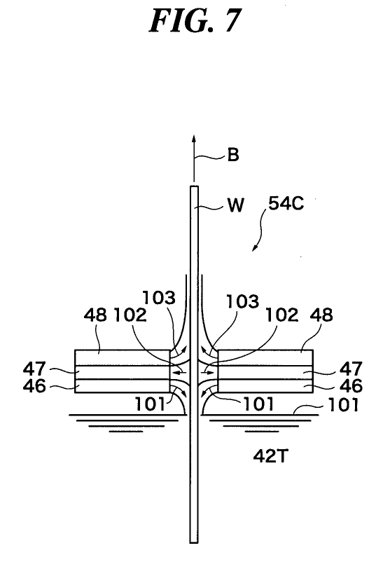

FIG. 7 is a schematic view of an example of general constitution of an essential part of the drying mechanism section in another embodiment. As shown, this drying mechanism section 54C has: liquid supply nozzles 46, suction nozzles 47, and gas supply nozzles 48, one each on both sides of the substrate W, with one nozzle placed over another. It is arranged that the liquid supply nozzles 46, suction nozzles 47, and gas supply nozzles 48 are fixed and the substrate W is moved up as indicated with the arrow B. The liquid supply nozzles 46, suction nozzles 47, and gas supply nozzles 48 extend parallel to the substrate W and at right angles to the arrow B direction to cover the diameter of the substrate W. It may also be arranged that the respective nozzles cover at least part of the substrate W and, while the substrate W is moved in the arrow B direction, move reciprocally in the direction parallel to the substrate W and at right angles to the arrow B so as to cover the diameter of the substrate W.

In the drying mechanism section 54C, while pulling up the substrate W from a cleaning tank 42T filled with the cleaning liquid 101, liquid (such as cleaning water) 101 is supplied from the liquid supply nozzle 46 to the both surfaces of the substrate W, residual liquid 102 remaining on the both surfaces of the substrate W is suctioned with the suction nozzle 47, and dry inert gas 103 is supplied from the gas supply nozzle 48 to remove by evaporation residual liquid slightly remaining on the both surfaces of the substrate W. Incidentally, the liquid supply nozzle 46 may be omitted depending on the case (for example in case the cleaning liquid in the cleaning tank 42T is of high cleanliness).

As described above, after suctioning and removing the residual liquid 102 with the suction nozzle 47, and supplying dry inert gas 103 from the gas supply nozzle 48 to remove by evaporation residual liquid slightly remaining on the both surfaces of the substrate W make it possible to suppress generation of watermarks. Although not shown in the drawing, a liquid film and liquid particle detection sensor for detecting the presence of liquid film and residual liquid particles on the both surfaces of the substrate W may be provided to adjust the liquid supply rate supplied from the liquid supply nozzle 46, the suction force of the suction nozzle 47, and the supply rate of gas supplied from the gas supply nozzle 48 in accordance with the detection output of the liquid film and liquid particle detection sensor. Therefore, it is possible to further suppress watermarks from being produced. It may also be arranged to adjust the temperature of the inert gas supplied from the gas supply nozzle 48.

Incidentally, the gas supplied from the gas supply nozzle 48 of the drying mechanism section 54B, 54C to the substrate W, like that from the gas supply nozzle 40 of the substrate processing apparatus 54, may be, besides the inert gas such as N₂ gas, a gas containing any of: ozone, hydrogen, oxygen, argon, carbon dioxide, water vapor, isopropyl alcohol (IPA) vapor, and air.

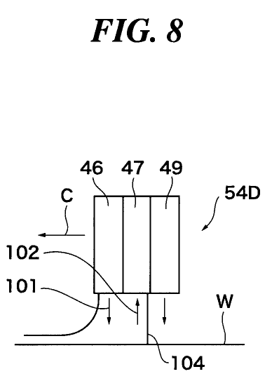

FIG. 8 is a schematic view of an example of general constitution of an essential part of the drying mechanism section in still another embodiment. As shown in the figure, the drying mechanism section 54D has a liquid supply nozzle 46, a suction nozzle 47, and an irradiation lamp 49 disposed in a row facing the substrate W in its diameter direction, so that the liquid supply nozzle 46, the suction nozzle 47, and the irradiation lamp 49 may be moved in the diameter direction (arrow C) of the substrate W. Liquid 101 is supplied from the liquid supply nozzle 46 to the top surface of the substrate W, and residual liquid 102 remaining on the top surface of the substrate W is suctioned with the suction nozzle 47 disposed adjacent to the liquid supply nozzle 46. After suctioning the cleaning liquid, light such as infrared radiation is cast from the irradiation lamp 49 onto the top surface of the substrate W to dry up, by evaporation, slightly remaining cleaning liquid. Here, as shown, a gas-liquid boundary plane 104 appears in the vicinity of boundary between the suction nozzle 47 and the irradiation lamp 49. The light from the irradiation lamp 49 is cast to part of the substrate W facing the space where no liquid is present.

When the cleaning liquid 101 is supplied from the liquid supply nozzle 46 to the top surface of the rotating substrate W, while moving the liquid supply nozzle 46, the suction nozzle 47 and the irradiation lamp 49 in the direction of diameter of the substrate W as described above, the cleaning liquid under centrifugal force flows toward the periphery (in the direction of arrow C) and residual liquid 102 on the top surface of the substrate W is suctioned with the suction nozzle 47. In this way, the top surface of the rotating substrate W remains covered and protected with the cleaning liquid until immediately before the suction, so that watermarks are suppressed from being produced. Further, slightly remaining cleaning liquid is dried by evaporation caused by casting the light of the irradiation lamp 49. The same liquid supply nozzle 46, suction nozzle 47 and irradiation lamp 49 described above may be disposed facing the reverse surface of the substrate W.

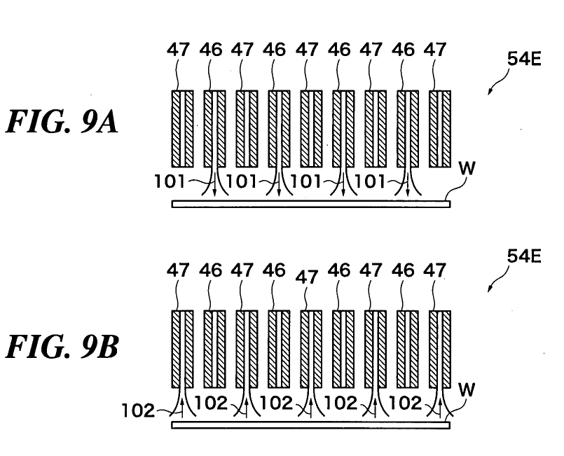

Each FIG. 9A and FIG. 9B is a schematic view of an example of general constitution of an essential part of the drying mechanism section in still another embodiment. As shown in the figure, the drying mechanism section 54E has liquid supply nozzles 46 and suction nozzles 47 in plural disposed in a row alternately in the diameter direction of the top surface of the substrate W. In the state of the substrate W being rotated, cleaning liquid 101 is supplied from the liquid supply nozzle 46 shown in FIG. 9A, followed by, as shown in FIG. 9B, suctioning with the suction nozzle 47 residual cleaning liquid 102 on the surface of the substrate W. Although not shown here, a liquid film and liquid particle detection sensor for detecting the presence of liquid film and residual liquid particles on the surface of the substrate W may be provided to control the liquid supply rate and supply time of the liquid supply nozzle 46, and the suction force and suction time of the suction nozzle 47, in accordance with the detection output of the liquid film and liquid particle detection sensor, so that watermarks are further suppressed from being produced. It is also possible to provide an irradiation lamp and a gas supply nozzle to cast light such as infrared radiation after suctioning residual liquid with the suction nozzle 47 and to supply inert gas from the gas supply nozzle (like the above example of gas supply from the gas supply nozzle 40 of the substrate processing apparatus 54). It is further possible to provide a liquid film and liquid particle detection sensor to adjust light exposure time, light intensity, gas supply rate, and gas temperature in accordance with the output of the sensor. It is also possible, like on the top surface, to provide the liquid supply nozzle 46 and the suction nozzle 47 on the reverse surface of the substrate W.

In the drying mechanism section of the above embodiments, when the liquid (such as the cleaning liquid) is supplied from the liquid supply nozzle onto the surface of the substrate W, the liquid bounces on the surface to produce mist. If the mist adheres to part of the surface of the substrate W, around the liquid supply nozzle, already finished with the drying process, the adhesion becomes the cause of watermarks. Therefore, providing a gas suction mechanism (atmosphere suction nozzle) for suctioning the mist and the like in the area surrounding the liquid supply nozzle makes it possible to effectively suction to remove such mist before it flies and re-adheres. Thus it is possible to further suppress watermarks from being produced.

An example is described below in which a gas suction mechanism is provided in the drying mechanism section 54D shown in FIG. 8. With the drying mechanism section 54D, while liquid is supplied from the liquid supply nozzle 46, not only liquid is suctioned with the suction nozzle 47 but also gaseous substance in the vicinity of the substrate W is suctioned to be collected. As a result, gaseous substance contained in liquid particles that have jetted out of the liquid supply nozzle 46, bounced on the substrate W, and dispersed around is suctioned to be collected. In other words, the suction nozzle 47 suctions to collect simultaneously gas and minute liquid particles present in the vicinity of the substrate W. In this way, not only suctioning liquid through the suction nozzle 47 simultaneously with supplying liquid from the liquid supply nozzle 46, but also suctioning to collect gaseous substance around the substrate W, makes it possible to efficiently suction to collect, with a small suction rate, the supplied liquid and gaseous substance containing minute liquid particles before they are dispersed in a wide range. It is also possible to dispose the suction nozzle 47 so that its suction port is open at a position surrounding the supply port of the liquid supply nozzle 46. In this way, it is possible to collect supplied liquid and flying minute liquid particles more efficiently before they are dispersed in a wide range.

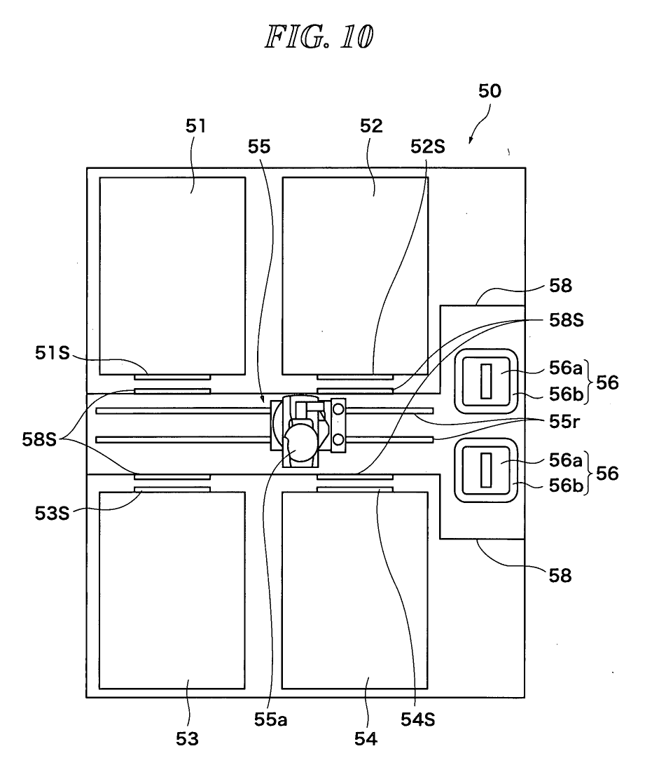

FIG. 10 is a schematic plan view of overall constitution of a substrate processing apparatus 50 according to the present invention. The substrate processing apparatus 50 is meant in a broad sense. The substrate processing apparatus 50 is constituted with: wet processing sections 51, 52, 53 for wet-processing the substrate, a drying mechanism section 54 for drying the substrate, a transfer section 55 for transferring the substrate, and loading and unloading sections 56, 56 for transferring in and out the substrate. In this embodiment, the wet processing section 51 is a roll cleaning machine, the wet processing section 52 is a pen cleaning machine, and the wet processing section 53 is a spurt suction cleaning machine. Incidentally, when the term “substrate processing apparatus 54” is simply mentioned in the following description, it means any one of the substrate processing apparatus 54, 54A through 54E.

With the substrate processing apparatus of the above constitution, a substrate is taken out of a cassette (not shown in the drawing) placed on one of the loading and unloading sections 56, 56 with the transfer section 55 made up of transfer robot and the like. The substrate is transferred for example through the wet processing section 51, the wet processing section 52, and the wet processing section 53 to carry out wet processing of the substrate in succession. The substrate finished with the wet processing is transferred with the transfer section 55 to the drying mechanism section 54. After the drying process, the substrate transferred with the transfer section 55 is contained into the cassette placed on the other one of the loading and unloading sections 56. Further details will be described below.

The substrate processing apparatus 50 shown in FIG. 10 is provided with two loading and unloading stages 56b on which a wafer cassette 56a for stocking a large number of substrates W is placed. The loading and unloading stages 56b may be provided with a mechanism for their vertical motion. A transfer robot 55a having two hands, one in upper and the other in lower position, is disposed on a running mechanism 55r, to be capable of reaching each wafer cassette 56a on the loading and unloading stages 56b. With the running mechanism 55r of the transfer robot 55a as a symmetry axis, the roll cleaning machine 51 and the pen cleaning machine 52 are disposed on one side, while the spurt suction cleaning machine 53 and the drying mechanism section 54 are disposed on the other side of the symmetry axis. The respective cleaning machines 51, 52, 53, and the drying mechanism section 54 are disposed in positions where the hands of the transfer robot 55a can reach.

Of the two hands of the transfer robot 55a, the lower hand is used only for taking the substrate W from the wafer cassette 56a, and the upper hand is used only for giving the substrate W back to the wafer cassette 56a. This arrangement is to prevent the substrate W from being contaminated by placing the clean substrate W after being cleaned on the upper side. The lower hand is of a suction type for vacuum-suctioning the substrate W, and the upper hand is a drop-in hand for gripping the periphery of the substrate W. The suction type hand is capable of accurate transfer irrespective of displacement of the substrate W in the cassette. The drop-in type hand is capable of transfer while keeping the reverse surface of the substrate W clean because the drop-in type hand, unlike the vacuum suction type, does not collect dust. Carrying the substrate W into and out of the respective cleaning machines 51, 52, 53 and the drying mechanism section 54 by means of the lower hand eliminates the possibility of the upper hand being contaminated with liquid drops of the rinsing water.

A partition 58 is provided in order to discriminate the cleanliness of the area B where the respective cleaning machines 51, 52, 53 and the drying mechanism section 54 are disposed from the cleanliness of the area A where the transfer section 55 and the loading and unloading sections 56 are disposed. Shutters 58s are provided at the opening of the partition for transferring the substrate W between both areas. The air pressure in the area B is set lower than that in the area A.

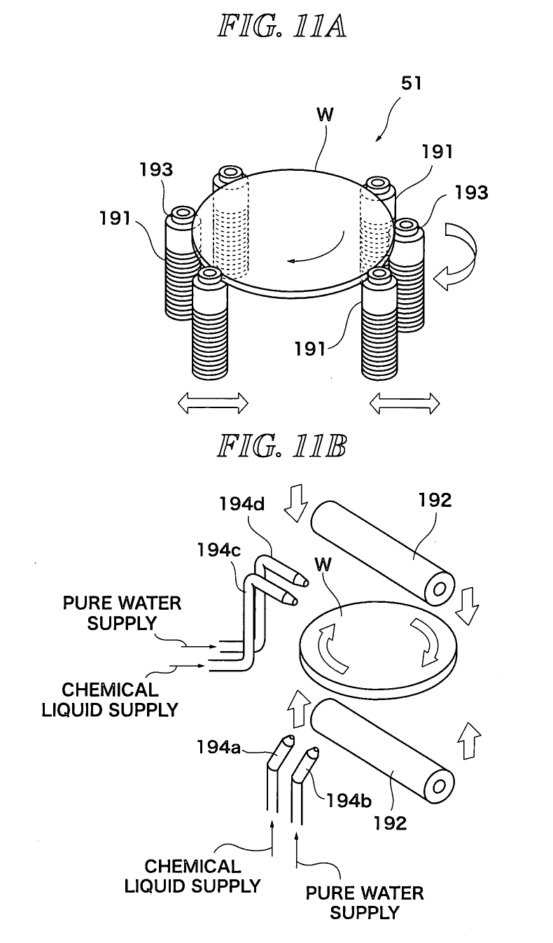

FIGS. 11A and 11B are schematic views of the roll cleaning machine 51. FIG. 11A is a schematic view of the rotating mechanism for rotating the substrate W in the roll cleaning machine 51. FIG. 11B is a schematic view of the cleaning mechanism for cleaning the substrate W in the roll cleaning machine 51. As shown in FIGS. 11A and 11B, the roll cleaning machine 51 is a low revolution cleaning unit of the so-called roll-roll type, and has plural upright rollers 191 for holding the substrate W and cleaning members 192 for roller type scrub cleaning made of sponge or the like.

The rollers 191 of the roll cleaning machine 51 are disposed to surround the substrate W and capable of moving inward and outward as shown in FIG. 11A. The top part of each roller 191 is formed with a holding groove 193. As the periphery of the substrate W is held in the holding groove 193, the substrate W is held with the rollers 191. The rollers 191 are also made capable of rotating so as to rotate the substrate W held with the rollers 191 as the rollers 191 rotates.

The cleaning members 192 have a roll-shaped member made of sponge for rotation about the roller axis. The cleaning members 192 are also made to be pressed, while being rotated about the axis of the roll-shaped member, against the substrate W to clean it. It is further possible to add megasonic type cleaning by casting ultrasonic waves to the cleaning liquid. As shown in FIG. 11B, the cleaning members 192 are disposed above and below the substrate W and capable of making vertical motion to come into contact with the substrate W. The roll cleaning machine 51 is provided with a chemical liquid nozzle 194a for supplying etching liquid and a pure water nozzle 194b for supplying pure water to the reverse surface of the substrate W, and with a chemical liquid nozzle 194c for supplying etching liquid and a pure water nozzle 194d for supplying pure water to the top surface of the substrate W. The roll cleaning machine 51 mainly plays the role of removing particles off the substrate W.

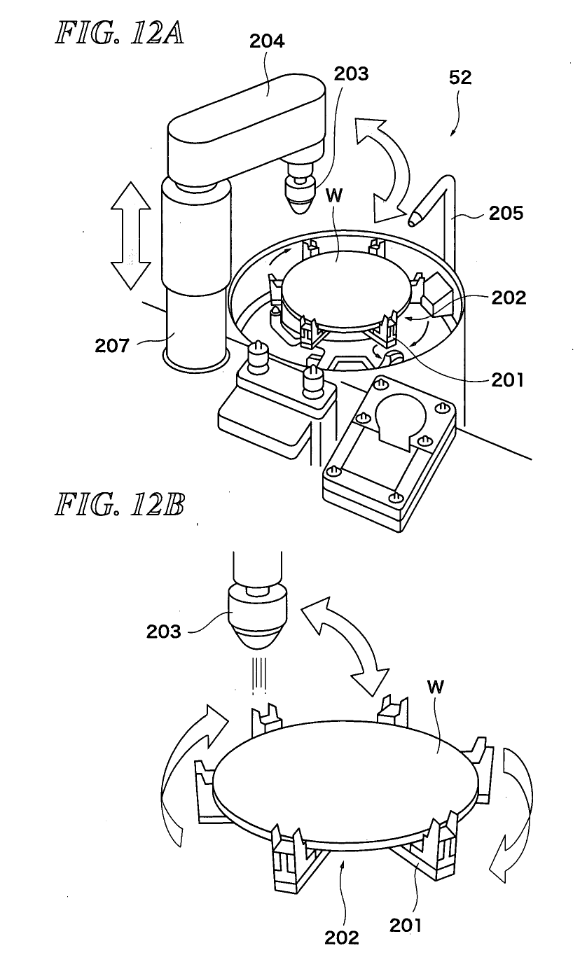

FIGS. 12A and 12B are schematic views of the pen cleaning machine 52. FIG. 12A schematically shows the overall constitution of the pen cleaning machine 52, and FIG. 12B schematically shows an essential part of the pen cleaning machine 52. As shown in FIGS. 12A and 12B, the pen cleaning machine 52 is provided with a rotary table 202 that includes arms 201, disposed radially at the top of a rotary shaft, for holding the substrate W, forming a high revolution type of cleaning unit. This rotary table 202 is capable of rotating the substrate W at high speeds of about 1500 to 5000 rpm.

As shown in FIG. 12A, the pen cleaning machine 52 is also provided with a swing arm 204 having a nozzle 203 having a hemispherical sponge body. The nozzle 203 is made capable of cleaning the substrate W by pressing the rotating hemispherical sponge body against the substrate W, and capable of simultaneously realizing megasonic type cleaning by casting ultrasonic waves to the cleaning liquid. The swing arm 204 is secured to a support shaft 207. The support shaft 207 is made capable of making both rotary and vertical motions. It is adapted that, as the support shaft 207 rotates, the swing arm 204 swings so that the nozzle 203 can take a cleaning position of the substrate W and a retracted position distant from the cleaning position. When the nozzle 203 is in the cleaning position, cleaning liquid vibrated with ultrasonic waves is supplied from the nozzle 203 to the top surface of the substrate W. As described above, the pen cleaning machine 52 is made as a high revolution type of cleaning unit of the so-called megasonic type.

Incidentally, the pen cleaning machine 52 is provided with a gas nozzle 205 for supplying inert gas and a heating means (not shown in the drawing) for accelerating drying by heating, thereby improving process performance and reducing cycle time.

The constitution of the spurt suction cleaning machine 53 and the drying mechanism section 54 is as described above. Whatever method is chosen, each cleaning machine is capable of supplying three or more kinds of cleaning liquid to top and reverse surfaces of the substrate W. The above cleaning liquid may be pure water. The stage for chucking the substrate W is capable of rotating at high speeds.

Further, using a cavi-jet type that utilizes the cavitation effect, in place of the megasonic type that can be mounted on the respective cleaning machines described above, can provide the same effect. Therefore, the cavi-jet type may be mounted. As shown in FIG. 10, the wafer feeding ports of the above cleaning machines 51, 52, 53 and the drying mechanism section 54 are respectively provided with shutters 51a, 52a, 53a and 54a so that the feeding ports may be opened only when the substrate W is carried in. Further, respective cleaning liquid supply lines (not shown in the drawing) are provided with pneumatically controlled constant flow rate valves (not shown) so that flow rate may be freely set on a control panel by combination with electro-pneumatic regulator that controls pneumatic pressure.

Next, in reference to FIGS. 10 through 12, cleaning steps will be described. The substrate W in the wafer cassette 56a is transferred with the transfer robot 55a to the roll cleaning machine 51. The substrate W is cleaned with the roll cleaning machine 51. In the roll cleaning machine 51, while the substrate W is held with the rollers 191, the upper and lower sponges (cleaning members) 192 are respectively moved downward and upward so that they are brought into contact with top and reverse surfaces of the substrate W. In this state, the top and reverse surfaces of the substrate W are entirely scrub-cleaned by supplying pure water from pure water nozzles 194b, 194d disposed above and below the substrate W.

After the scrub cleaning, the sponge rollers 192 are respectively retracted upward and downward, etching liquid is supplied from the liquid agent nozzles 194a, 194c to the top and reverse surfaces of the substrate W to etch (chemically clean) the top and reverse surfaces of the substrate W, and residual metallic ions on the top and reverse surfaces of the substrate W are removed. Here, the rotation speed of the substrate W is changed as required. After that, pure water is supplied from the pure water nozzles 194b, 194d to the top and reverse surfaces of the substrate W, and the etching liquid is removed by pure water replacement for a predetermined period of time. Also here, the rotation speed of the substrate W is changed as required.

The substrate W cleaned with the roll cleaning machine 51 is transferred with the transfer robot 55a to the pen cleaning machine 52. In the pen cleaning machine 52, the substrate W is held on the rotary table 202 and rotated at low speeds of about 100 to 500 rpm. While swinging the swing arm 204 over the entire surface of the substrate W and supplying pure water, vibrated with ultrasonic waves, from the nozzle 203 provided at the fore-end of the swing arm 204, the hemispherical sponge roller is rotated and pressed against the substrate W to clean the substrate W by removing particles. After particles are removed, supply of pure water is stopped and the swing arm 204 is returned to a standby position.

The substrate W cleaned with the pen cleaning machine 52 is transferred with the transfer robot 55a to the spurt suction cleaning machine 53. In the spurt suction cleaning machine 53, spurt suction cleaning is made as described above. The substrate W finished with the spurt suction cleaning with the spurt suction cleaning machine 53 is transferred with the transfer robot 55a to the drying mechanism section 54. In the drying mechanism section 54, as described above, fluid in the vicinity of the substrate W and minute particles contained in the fluid are suctioned to be collected. At the same time, the substrate W is spin dried by rotating it at high speeds of about 1500 to 5000 rpm, while supplying as required clean inert gas. The substrate W dried with the drying mechanism section 54 is handed over to the transfer robot 55a and returned to the wafer cassette 56a on the loading and unloading stage 56b.

It is constituted that the cleaning liquid supplied to respective cleaning machines, cleaning method, and cleaning time may be freely set on the control panel. A guide is provided at the base portion of the cleaning chamber (area B), so that the type of the cleaning machine may be easily changed by introducing a cleaning machine into the guide. A positioning mechanism is also provided so that the machine is in the same position after being replaced.

While the substrate processing apparatus 50 is described above on the assumption that the wet processing section 51 is a roll cleaning machine and the wet processing section 52 is a pen cleaning machine, the combination may be changed for example that the wet processing section 51 is a CMP and the wet processing section 52 is a roll cleaning machine, or that the wet processing section 51 is a bevel polishing machine and the wet processing section 52 is a chemical liquid cleaning machine. The substrate processing apparatus may also be constituted by appropriate combination of respective wet processing sections such as cleaning module, CMP, plating machine, bevel polishing machine, and etching machine. Also the drying mechanism section 54 may be any drying mechanism, other than spin drying, such as gas blow drying, IPA drying, and lamp exposure drying.

Providing an antistatic mechanism in the substrate processing apparatus described above makes it possible to prevent the substrate W from being affected with static-electrical charges, thereby preventing the substrate W from being damaged by static-electrical charges. As the antistatic mechanism, for example an ionizer (a device that ionizes air by the use of corona discharge, soft X-rays, etc.) may be disposed along the underside of an HEPA filter disposed above the wet processing sections 51, 52, 53, and the drying mechanism section 54. The antistatic process of the substrate W may be carried out while spraying air ionized with the ionizer to the substrate W being processed with the wet processing sections 51, 52, 53, and the drying mechanism section 54.

Another antistatic mechanism may be constituted in the drying mechanism section 54A as follows: In the casing 27, a clean air blow-out port and a suction port of an exhaust duct are disposed facing to each other on both sides of the liquid collection cover 25A at about the same height as the top edge of the liquid collection cover 25A. An ionizer is disposed at the blow-out port to blow out air ionized with the ionizer, and the air is suctioned into the suction port. In this way, the substrate W may be processed free from static-electric charges as the process goes on by spraying ionized air to the substrate W.

While embodiments of the invention are described above, the present invention is not limited to such embodiments, but may be modified in various ways within the scope of the claims, and within the scope of technical ideas described in the specification and drawings. Further, any shape, constitution, and material not described explicitly in the specification and drawings are included within the scope of technical ideas of this invention as long as they exhibit the same functions and effects as those of this invention. For example, the substrate processing liquid supply nozzle 20 and the suction nozzle 21, which are provided in the substrate processing apparatus 53, and the gas supply nozzle 40 and the suction section 41, which are provided in the substrate processing apparatus 54, may be provided together in a single substrate processing apparatus. In that case, substrate processing and substrate cleaning are carried out by spurting substrate processing liquid from the substrate processing liquid supply nozzle 20 and substrate drying is carried out by supplying gas jet from the gas supply nozzle 40. Further, the substrate processing apparatus 53 and other drying mechanism sections 54A through 54E may be provided together in a single substrate processing apparatus. In other words, it is possible to constitute a so-called single module by integrating an apparatus for cleaning the substrate W and an apparatus for drying it into a single apparatus.

1. A substrate processing apparatus comprising:
a fluid supply means for supplying fluid to a substrate; and
a fluid collection means for collecting the fluid in a vicinity of the substrate, the fluid collection means having a fluid suction section, the fluid suction section having an opening in a vicinity of a fluid spurt section of the fluid supply means.

2. The substrate processing apparatus as recited in claim 1, wherein the fluid collection means is constituted to suction and collect the fluid floating in the vicinity of the substrate and minute particles contained in the fluid as a result of the fluid having been spurted from the fluid support section to the substrate.

3. The substrate processing apparatus as recited in claim 1, comprising:
a control means for controlling the fluid supply means and the fluid collection means; and
a measuring means for measuring at least one of conditions of atmosphere around the substrate, consisting of humidity, gas component, gas concentration, number of particles, and particle component;
wherein measurement results with the measuring means are fed back to the control means to control supply of the fluid from the fluid supply means and collection of the fluid to the collection means, so that the atmosphere is kept to predetermined conditions according to the measurement results of the atmosphere around the substrate.

4. The substrate processing apparatus as recited in claim 1, wherein the fluid supplied from the fluid supply means to the substrate is at least one fluid selected from a group consisting of: pure water; gas solution water containing any of ozone, hydrogen, oxygen, nitrogen, argon, and carbon dioxide; chemical liquid containing any of isopropyl alcohol, fluoric acid, and sulfuric acid; and gas containing any of ozone, hydrogen, oxygen, nitrogen, argon, carbon dioxide, water vapor, IPA vapor, and air.

5. The substrate processing apparatus as recited in claim 4, wherein,
the fluid supply means has a supply mechanism for supplying to the substrate plural kinds of the pure water, gas solution water, chemical liquid, and gas; and
the fluid collection means has a collection mechanism for simultaneously suctioning and collecting gaseous substance and minute particles floating in the vicinity of the substrate as a result of plural kinds of the pure water, gas solution water, chemical liquid, and gas being supplied from the supply mechanism to the substrate.

6. The substrate processing apparatus as recited in claim 1, wherein the fluid supply means is one of an ultrasonic jet, two-fluid jet, mist jet, and liquid jet for spurting minute liquid particles to the substrate, and a dry ice jet, ice jet, and microcapsule jet for spurting minute solid particles to the substrate.

7. The substrate processing apparatus as recited in claim 1, wherein the fluid suction section is a liquid suction mechanism for suctioning liquid adhering to a surface of the substrate.

8. The substrate processing apparatus as recited in claim 7, further comprising: an evaporation acceleration mechanism for accelerating evaporation of the liquid after suctioning the liquid with the fluid suctioning mechanism by applying to the substrate surface at least one selected from a group consisting of: lamp exposure, gas supply, sound wave exposure, alcohol liquid supply, and alcohol vapor supply.

9. The substrate processing apparatus as recited in claim 7, further comprising: a liquid supply mechanism for keeping supplying the liquid to the substrate surface until immediately before the liquid is suctioned with the liquid suctioning mechanism.

10. A substrate processing apparatus comprising:
a liquid supply mechanism for supplying liquid to a substrate surface;
a liquid suction mechanism for suctioning the liquid adhering to the substrate surface;
an evaporation accelerating mechanism for accelerating evaporation of the liquid by applying to the substrate at least one of lamp exposure and gas supply;
a liquid film and liquid particle detection sensor for detecting residual liquid particles and a presence of liquid films on the substrate surface; and
a control means for performing, according to a state of the residual liquid particles and the presence of liquid films on the substrate surface detected with the liquid film and liquid particle detection sensor, at least one control selected from a group consisting of: control of at least one of liquid supply rate and liquid supply time with the liquid supply mechanism, control of at least one of suction time and suction speed with the liquid suction mechanism, control of at least one of lamp exposure time and light intensity with the evaporation accelerating mechanism, and control of at least one of gas spurt time and gas temperature with the evaporation accelerating mechanism.

11. The substrate processing apparatus as recited in claim 7, further comprising a gaseous substance suction mechanism for suctioning atmosphere in a vicinity of the substrate surface.

12. The substrate processing apparatus as recited in claim 1, further comprising:
a transfer section for transferring the substrate; and
a loading and unloading section for transferring in and out the substrate.

13. A substrate processing method comprising:
a fluid supply step of supplying fluid to a substrate; and
a fluid collection step of collecting the fluid in a vicinity of the substrate in a vicinity of a supply point of the fluid supplied in the fluid supply step.

14. The substrate processing method as recited in claim 13, wherein the fluid is spurted to the substrate in the fluid supply step, and the fluid and the minute particles contained in the fluid floating in the vicinity of the substrate as a result of the spurt are suctioned to be collected in the fluid collection step.

15. The substrate processing method as recited in claim 13, comprising:
a control step of controlling the fluid supply step and the fluid collection step; and
a measuring step of measuring at least one atmospheric condition out of: humidity, gas component, gas concentration, number of particles, and particle component, around the substrate,
wherein measurement results by the measuring step are fed back to the control step to control supply of the fluid in the fluid supply step and collection of the fluid in the fluid collection step so that the atmosphere is kept to predetermined conditions according to the measurement results of the atmosphere around the substrate.

16. The substrate processing method as recited in claim 13, wherein the fluid supplied by the fluid supply step is at least one fluid selected from a group consisting of: pure water; gas solution water containing any of ozone, hydrogen, oxygen, nitrogen, argon, and carbon dioxide; chemical liquid containing any of isopropyl alcohol, fluoric acid, and sulfuric acid; and gas containing any of ozone, hydrogen, oxygen, nitrogen, argon, carbon dioxide, water vapor, IPA vapor, and air.

17. The substrate processing method as recited in claim 16, wherein
the fluid supply step includes a supply step of supplying to the substrate plural kinds of the pure water, gas solution water, chemical liquid, and gas; and
the fluid collection step includes a collection step of suctioning and collecting simultaneously gaseous substance and minute particles floating in the vicinity of the substrate as a result of the plural kinds of the pure water, gas solution water, chemical liquid, and gas being supplied to the substrate in the supply step.

18. The substrate processing method as recited in claim 13, wherein the fluid supply step supplies the fluid by at least one jet selected from a group consisting of an ultrasonic jet, a two-fluid jet, a mist jet, and a liquid jet for spurting minute liquid particles to the substrate; and a dry ice jet, an ice jet, and a microcapsule jet for spurting minute solid particles to the substrate.

19. The substrate processing method as recited in claim 13, wherein the fluid suction step is a liquid suction step of suctioning liquid adhering to the substrate surface.

20. A substrate processing method, wherein gaseous substance around a position of a substrate toward which a fluid is supplied to the substrate and minute particles contained in the gaseous substance are suctioned and collected simultaneously with supplying the fluid to the substrate.

21. A substrate processing method comprising the steps of:
processing a substrate by supplying liquid to a surface of the substrate; and
suctioning the liquid adhering to the substrate surface.

22. The substrate processing method as recited in claim 21 further comprising the step of:
accelerating evaporation of the liquid after suctioning to remove the liquid adhering to the substrate surface by applying to the substrate surface at least one selected from a group consisting of: lamp exposure, gas supply, sound wave exposure, alcohol liquid supply, and alcohol vapor supply.

23. The substrate processing method as recited in claim 22 further comprising the step of:
changing, according to a state of residual liquid particles and the presence of liquid films on the substrate surface, at least one selected from a group consisting of: at least one of the liquid supply rate and liquid supply time; at least one of the liquid suction time and liquid suction speed; at least one of the lamp exposure time and light intensity of the lamp; at least one of the sound wave exposure time and sound wave intensity; and at least one of supply time and temperature of the alcohol liquid or alcohol vapor.

24. The substrate processing method as recited in claim 21, wherein the liquid is kept supplied to the substrate until immediately before the start of suction of the liquid.
